(19) United States
(12) Patent Application Publication
(10) Pub. No.: US 2021/0040829 A1
(43) Pub. Date: Feb. 11, 2021

(54) STATISTICS AND PHYSICS-BASED MODELING OF WELLBORE TREATMENT OPERATIONS

(71) Applicant: Halliburton Energy Services, Inc., Houston, TX (US)

(72) Inventor: Srinath Madasu, Houston, TX (US)

(21) Appl. No.: 16/478,454

(22) PCT Filed: Apr. 19, 2017
(86) PCT No.: PCT/US2017/028428

§ 371 Date: Jul. 16, 2019

(51) Int. Cl. E21B 43/26; G06K 9/62; G06F 30/27; E21B 21/08

(52) U.S. Cl. CPC E21B 43/26; E21B 21/08; G06F 30/27; G06K 9/6276

(57) ABSTRACT

A current value of at least one operational attribute of a current treatment stage of multiple treatment stages of a wellbore treatment operation of a current well in real time is determined. A determination is made of whether a statistics-based model criteria has been satisfied. In response to determining that the statistics-based model criteria is not satisfied, a response to the current stage of the wellbore treatment operation is predicted based on a physics-based model. In response to determining that the statistics-based model criteria is satisfied, the response to the current stage is predicted based on a statistics-based model. A next value of the at least one operational attribute for a next stage is selected based on the predicted response. Adjustment of the next stage of the wellbore treatment operation is initiated based on the next value of the at least one operational attribute.

### BACKGROUND

The present disclosure relates generally to wellbore treatment operations and, more particularly, to statistics and physics-based modeling of wellbore treatment operations.

Treatment fluids can be used in a variety of subterranean treatment operations. As used herein, the terms “treat,” “treatment,” “treating,” etc. refer to any subterranean operation that uses a fluid in conjunction with achieving a desired function and/or for a desired purpose. Use of these terms does not imply any particular action by the treatment fluid. Illustrative treatment operations can include, for example, fracturing operations, gravel packing operations, acidizing operations, scale dissolution and removal, consolidation operations, and the like.

In some applications, treatment operations may include a diverting agent or diverter. For example, after a wellbore is drilled in a subterranean producing zone, a treatment fluid can be introduced into the zone. For example, a producing zone can be stimulated by introducing an aqueous acid solution into the matrix of a producing zone to dissolve formation material or materials near the wellbore which impede well productivity. Such stimulation of the producing zone can increase its porosity and permeability. This results in an increase in the production of hydrocarbons therefrom. To ensure that the producing zone is contacted by the treating fluid uniformly, a diverting agent may be placed in the zone to direct the placement of a desired treatment fluid.

One diversion approach is to pack the diverting agent in perforation tunnels extending from the wellbore into the subterranean zone. The diverting agent in the perforation tunnels causes the treating fluid introduced therein to be uniformly distributed between all of the perforations whereby the subterranean zone is uniformly treated. The term “zone,” as used herein, simply refers to a portion of the formation and does not imply a particular geological strata or composition.

Another example of a subterranean treatment that often uses an aqueous treatment fluid is hydraulic fracturing. In a hydraulic fracturing treatment, a viscous fracturing fluid is introduced into the formation at a high enough rate to exert sufficient pressure on the formation to create and/or extend fractures therein. The viscous fracturing fluid suspends proppant particles that are to be placed in the fractures to prevent the fractures from fully closing when hydraulic pressure is released, thereby forming conductive channels within the formation through which hydrocarbons can flow toward the wellbore for production.

In certain circumstances, variations in the subterranean formation will cause the fracturing fluid to create and/or extend fractures non-uniformly. Typically, one or more dominant fractures may extend more rapidly than nondominant fractures. These dominant fractures utilize significantly more fracturing fluid than non-dominant fractures, thereby reducing pressure on non-dominant fractures and slowing or stopping their extension. Dominant fractures can be identified using fiber optics to measure fluid flow rates to each fracture and/or using micro-seismic sensors to detect the growth rate of the fractures. Operators have addressed the unbalanced distribution of fracture fluid by introducing a certain quantity of diverters into the fracturing fluid when dominant fractures are identified. The diverters travel to the dominant fractures and restrict the flow of fracturing fluid to the dominant fractures or plug the dominant fractures. In some applications, these diverters are composed of degradable materials, including water-hydrolysable materials such as polylactic acid, which degrade over time and restore permeability to plugged or restricted fractures.

### BRIEF DESCRIPTION OF THE DRAWINGS

Examples of the disclosure can be better understood by referencing the accompanying drawings.

FIG. 1 depicts a diagram of a computational representation of a wellbore and the underlying formation geometry, according to some embodiments.

FIG. 2 depicts a flowchart of operations for coupled statistics-based and physics-based modeling of wellbore treatment operations, according to some embodiments.

FIG. 3 depicts a flowchart of operations for statistics-based modeling of wellbore treatment operations, according to some embodiments.

FIG. 4 depicts an example Nearest Neighbor Learning (NNL) regional model applicable in a multi-well statistics-based modeling of wellbore treatment operations, according to some embodiments.

FIG. 5 depicts an example graph illustrating a normalized comparison of responses over multiple stages between predicted response values using NNL modeling and actual response values, according to some embodiments.

FIG. 6 depicts an example wellbore treatment or stimulation system, according to some embodiments.

FIG. 7 depicts an example fracturing operation being performed in a subterranean formation, according to some embodiments.

FIG. 8 depicts an example acidizing operation being performed in a subterranean formation.

FIG. 9 depicts an example use of a diverter in a subterranean formation with multiple zones, according to some embodiments.

FIG. 10 depicts an example computer device, according to some embodiments.

### DESCRIPTION

The description that follows includes example systems, methods, techniques, and program flows that embody examples of the disclosure. However, it is understood that this disclosure can be practiced without these specific details. For instance, this disclosure refers to modeling for fluid diversion in illustrative examples. Examples of this disclosure can be also applied to other types of downhole and surface treatment operations. Other instances, well-known instruction instances, protocols, structures and techniques have not been shown in detail in order not to obfuscate the description.

Various embodiments include a coupling of statistics-based modeling with physics-based modeling of various wellbore treatment operations, such as fracturing, diversion, acidizing applications, etc. along a wellbore to enhance hydrocarbon recovery. Such coupled modeling can be performed in real time during these wellbore treatment operations, thereby allowing for real time adjustments and control.

For example, a diversion can include multiple stages, wherein each stage includes one or more operational attributes (e.g., well pressure, tip pressure, flow rate, diverter mass, etc.). A pressure response from a current stage of the diversion can be predicted based on the coupling of statistics-based modeling with physics-based modeling. This predicted pressure response can then be used to set one or more operational attributes in a subsequent stage of the diversion.

In some embodiments, the statistics-based model is based on Nearest Neighbor Learning (NNL). The statistics-based model can be used to resolve the time and spatial variation of the response of a current stage for a subsequent stage of a wellbore treatment operation if values of the operational attributes of the current stage are within a range defined by previous values of the operational attributes. However, if values of the operational attributes of the current stage are not within a defined range, the physics-based model can be used to predict a response to the current stage. This coupled modeling allows for a faster computation of predicted responses in comparison to a strict physics-based modeling. This is because the physics and engineering aspects can be complicated and the data involved in the physics-based modeling can come with uncertainty. In turn, this coupled modeling can be applied in real time to adjust across a multi-stage wellbore treatment operation. Thus, various embodiments can overcome the handling of complicated physics using a robust, stable and accurate numerical solution throughout the different stages of wellbore treatment operations. Also, predictions of responses to the different stages can be accurately quantified.

In some embodiments, the statistics-based model can incorporate operational attributes from other wells or formations. These operational attributes from other wells or formations can provide information to the statistics-based model and increase the prediction accuracy for a predicted pressure response. The statistics-based model can use weights to increase or decrease the extent to which these supplemental operational attributes from other wells or formations influence predicted pressure values. Also, values of these weights can be based on various physical or geographic factors (e.g., geographic distance, similarity of formation geology, similarity in in vertical depth, similarity in equipment, etc.).

### Example Computational Representation of a Wellbore

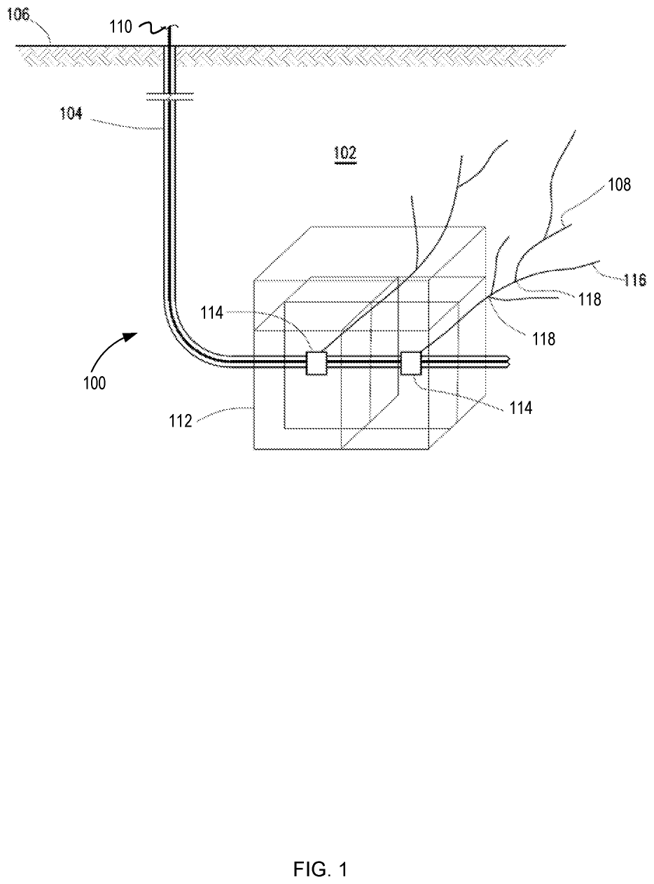

FIG. 1 depicts a diagram of a computational representation of a wellbore and the underlying formation geometry, according to some embodiments. A wellbore system 100 depicted in FIG. 1 comprises a wellbore 104 penetrating at least a portion of a subterranean formation 102. The wellbore 104 comprises one or more injection points 114 where one or more fluids may be injected from the wellbore 104 into the subterranean formation 102. In some embodiments, the wellbore pressure at these injection points 114 may be an operational attribute for an integrated diversion model. The subterranean formation 102 comprises pores initially saturated with reservoir fluids (e.g., oil, gas, and/or water). Initially, the computational blocks 112 are at a structural equilibrium, and the fluids in the subterranean formation 102 are at rest. In certain embodiments, a formation stress field may be determined using a geomechanical model based, at least in part, on computational blocks 112 representing the formation. In certain embodiments, the wellbore system 100 may be stimulated by the injection of a fracturing fluid at one or more injection points 114 in the wellbore 104. In certain embodiments, the one or more injection points 114 may correspond to injection points 114 in a casing of the wellbore 104.

When fluid enters the subterranean formation 102 at the injection points 114, one or more fractures 116 are opened, and the pressure difference between the solid stress and the fracture 116 causes flow into the fracture 116. In certain embodiments, a diverting agent may enter the injection point 114 and restrict the flow of further fluid. In some embodiments, the fracturing fluid may comprise a diverter. Flow restriction caused by the diverter may increase the surface pressure.

The subterranean formation 102 may comprise any subterranean geological formation suitable for fracturing (e.g., shale) or acidizing (e.g., carbonate), or any other type of treatment operation. As depicted in FIG. 1, the subterranean formation 102 comprises at least one fracture network 108 connected to the wellbore 104. The fracture network 108 may comprise a plurality of junctions 340 and a plurality of fractures 116.

The fracture network 108 shown in FIG. 1 contains a relatively low number of junctions and fractures 116. A fracture network may comprise of a wide range of junctions and fractures 116. The number of junctions and fractures 116 may vary drastically and/or unpredictably depending on the specific characteristics of the subterranean formation 102. For example, the fracture network 108 may comprise on the order of thousands of fractures 116 to tens of thousands of fractures 116.

In certain embodiments, an operational attribute to the statistics-based model or the integrated diversion model may comprise one or more wellbore treatment control inputs, sensor-acquired measurements, and/or one or more formation inputs. In certain embodiments, the one or more operational attributes may characterize a treatment operation for a wellbore 104 penetrating at least a portion of a subterranean formation 102. For example, in certain embodiments, the one or more operational attributes may include, but are not limited to an amount of diverter pumped into the wellbore system 100, the wellbore pressure at the injection points 114, the flow rate at the wellbore inlet 110, the pressure at the wellbore inlet 110, a wellbore depth, a wellbore diameter, a number of perforation clusters in a casing, a perforation cluster length, a perforation diameter, a distance between perforation clusters, a diverter particle diameter, and any combination thereof and any combination thereof. In certain embodiments, the one or more operational attributes may comprise real-time measurements. In some embodiments, real-time measurements comprise at least one of pressure measurements and flow rate measurements. In certain embodiments, real-time measurements may be obtained from one or more wellsite data sources. Wellsite data sources may include, but are not limited to flow sensors, pressure sensors, thermocouples, and any other suitable measurement apparatus. In certain embodiments, wellsite data sources may be positioned at the surface, on a downhole tool, in the wellbore 104 or in a fracture 116. Pressure measurements may, for example, be obtained from a pressure sensor at a surface of the wellbore 104.

In certain embodiments, the formation stress field determined by an integrated diversion model may be used, at least in part, to determine whether to use a diverter, to determine how much diverter to use, to develop a diverter pumping schedule, or any combination thereof. For example, in certain embodiments, flow rates and/or pressure sensors may be positioned at the wellbore inlet 110 of the wellbore 104 to measure the flow rate and pressure in real time. The measured inlet flow rate and pressure data may be used as operational attributes. In some embodiments, the one or more formation inputs may characterize the subterranean formation 102. In certain embodiments, the one or more formation inputs may include one or more properties of the subterranean formation 102, including, but not limited to the geometry of the subterranean formation 102, the natural stress field, pore pressure, formation temperature, and any combination thereof. In some embodiments, an earth model may provide one or more formation inputs.

### Example Operations

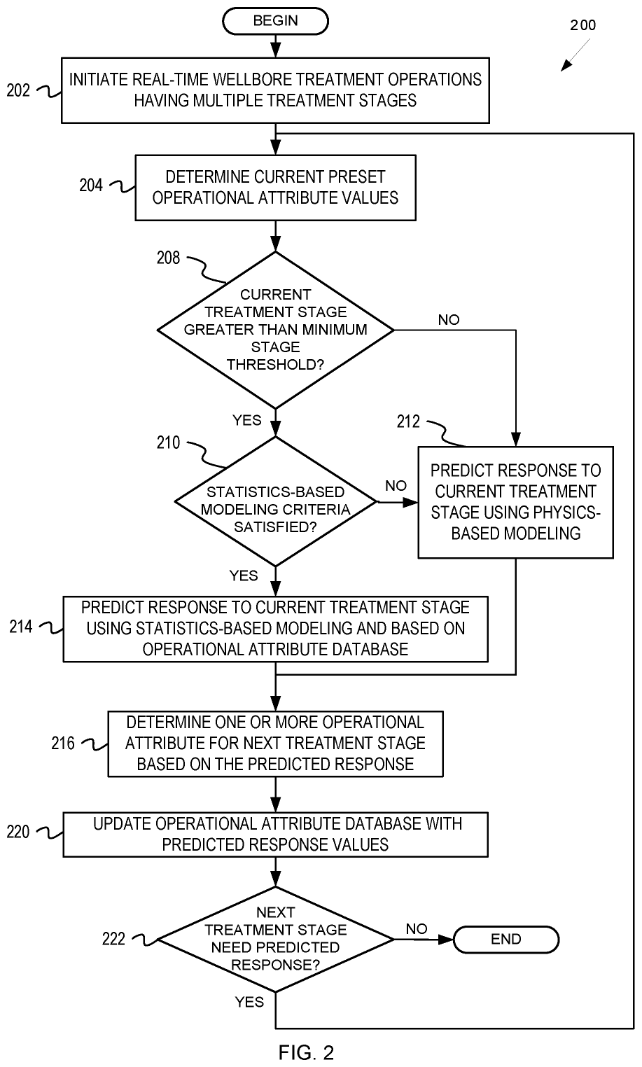

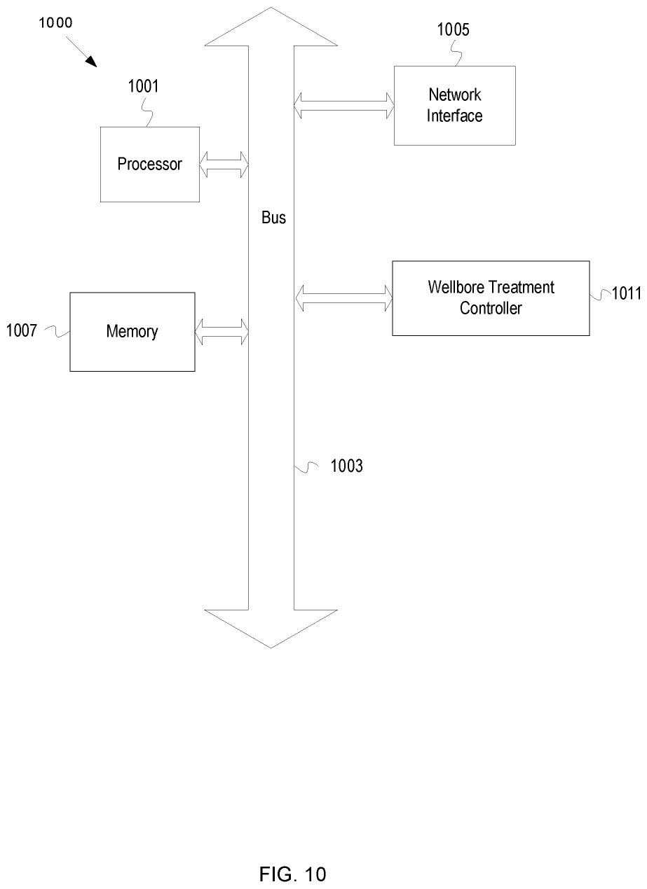

FIG. 2 depicts a flowchart of operations for coupled statistics-based and physics-based modeling of wellbore treatment operations, according to some embodiments. Operations of a flowchart 200 of FIG. 2 can be performed by software, firmware, hardware or a combination thereof For example, with reference to FIG. 10 (further described below), a processor in a computer device located at the surface can execute instructions to perform operations of the flowchart 200. Operations of the flowchart 200 begin at block 202.

At block 202, real-time wellbore treatment operations having multiple treatment stages are initiated. In one example, the treatment stages could be diverter injection stages. In another example, the treatment stages could be fracture treatment stages. In another example, the treatment stages can be acidization stages. Each treatment stage can have operational attributes that can varying values between treatment stages. Examples of operational attributes can include values such as sand size, flow rates, surface pressure, well pressure, tip pressure, diverter mass, etc. The operational attributes can be subdivided into two groups: preset operational attributes and predicted responses. Values of preset operational attribute can be used as inputs to a statistics-based or physics-based method to determine the values of predicted responses. The predicted responses are operational attributes with values that can be predicted/determined by preset operational attribute values. In one example, an operational attribute can be only a preset operational attribute or a predicted response. In another example, an operational attribute can be both a preset operational attribute and a predicted response. To illustrate, Table 1 depicts example operational attributes with values that can vary between each treatment stages for a diversion treatment operation and includes four example operational attributes: 1) the well pressure, 2) the actual diverter added, 3) the flow rate, and 4) a diverter pressure response. In Table 1, the unit of measurement for the well pressure and the diverter pressure response is pounds per square inch (PSI). The unit of measurement for flow rate is barrel per minute (BPM). The unit of measurement for the actual diverter added is pounds (lbs.). In the operations described below, the well pressure, actual diverter added, and flow rate are preset operational attribute, and the diverter pressure response is a predicted response:

TABLE 1

| | | Actual | | Diverter |
|---|---|---|---|---|
| | Well | Diverter | Flow | Pressure |
| Treatment | Pressure | Added | Rate | Response |
| stage | (psi) | (lbs) | (bpm) | (psi) |
| 1 | 2.84e7 | 30 | 0.010 | 500 |
| 2 | 2.89e7 | 40 | 0.015 | 1500 |
| 3 | 2.83e7 | 50 | 0.037 | 2000 |
| 4 | 2.85e7 | 40 | 0.030 | — |
| (current) | | | | |

At block 204, current preset operational attributes of the current treatment stage are determined. A current treatment stage is defined as the most recent treatment stage during which physical or computational activity is still to be performed. For example, with respect to Table 1, the fourth treatment stage is designated as the current treatment stage because the previous three stages have already experienced diversion treatment operations and the fourth treatment stage has not yet been completed. The values of the three preset operational attributes of “well pressure,” “actual diverter added,” and “flow rate” are determined at this stage. Determining these operational attributes can be performed passively, such as by measuring these values with an electronic instrument, or performed actively, such as by setting them directly.

In some embodiments, at least one operational attribute, such as well pressure, may be set in order to match a predicted response value with a goal response value. The goal response value can be a value that would result in improved performance of the well operation and depends on the specific goals of the overall well project. In one example, a goal response value can be 1800 psi for the diverter pressure response at the fourth stage. In another example, a goal response value can be 1.0 bpm for the flow rate throughout the first five stages.

At block 208, a determination is made of whether the current treatment stage is greater than a minimum stage threshold. The minimum stage threshold can provide a limitation to ensure that enough records are provided to allow a statistical method to generate a sufficiently accurate prediction instead of an inaccurate prediction. For example, the minimum stage threshold can be three, which will ensure only the fourth or greater stage will exceed the minimum stage threshold. If the minimum stage threshold is not exceeded by the current treatment stage, the operations continue at block 210. However, if the minimum stage threshold is exceeded by the current treatment stage, the operations continue block 212.

At block 210, a determination is made of whether a statistics-based modeling criteria is satisfied. This statistics-based modeling criteria can be based on values of one or more operational attributes from previous treatment stages. These values can be stored in different types of data structures in different types of media. For example, these values can be stored in tables in an operational attribute database. For example, with reference to Table 1, during the fourth treatment stage, the operational attribute database comprises three records of previous stages, wherein each record of a previous stage includes a set of operational attributes for a single treatment stage. In some examples, a list of previous values for each operational attribute can form a statistical range for each operational attribute. The statistical range for each operational attribute can be a numeric range, having a minimum value equal to the least value of the list of previous values and a maximum value equal to the greatest value of the list of previous values. Additionally, this list of previous values can be compiled and compared with the value of the current operational attribute.

The statistics-based modeling criteria can vary based on one or more of the different operational attributes. For example, the statistics-based modeling criteria can be that the value for each current preset operational attribute is within the statistical range. In another example, the statistics-based modeling criteria can be that the value of a specific operational attribute such as well pressure is less than or greater than any previous value in the statistical range for that same operational attribute. The statistics-based modeling criteria can be that the value for each current operational attribute is within two standard deviations of the mean value of the statistical range, wherein the standard deviation is based on the statistical range. In another instance, the statistics-based modeling criteria may be that each value of the preset operational attributes does not exceed one standard deviation of the maximum or minimum values of the statistical range. In another example, the statistics-based modeling criteria may be a combination of any of the above criteria. In one example, with respect to Table 1, the statistics-based modeling criteria can be that the current flow rate value is within the range of the statistical range. Then, for the current value of flow rate of 0.030 bpm, the criteria is satisfied because 0.030 bpm is within the range of 0.010 bpm and 0.037 bpm. If the statistics-based modeling criteria is satisfied, operations of the flowchart 200 continue at block 214 (which is further described below). If the statistics-based modeling criteria is not satisfied, then the operations of the flowchart 200 continue at block 212, where the physics-based model is used to predict the response.

At block 212, a response is predicted for the current treatment stage using a physics-based model. Examples of a physics-based model can include a fluid flow model, a proppant transport model, a diverter transport model, a junction model, etc. An example physics-based model is described below in the section titled “Example Physics-Based Model.”

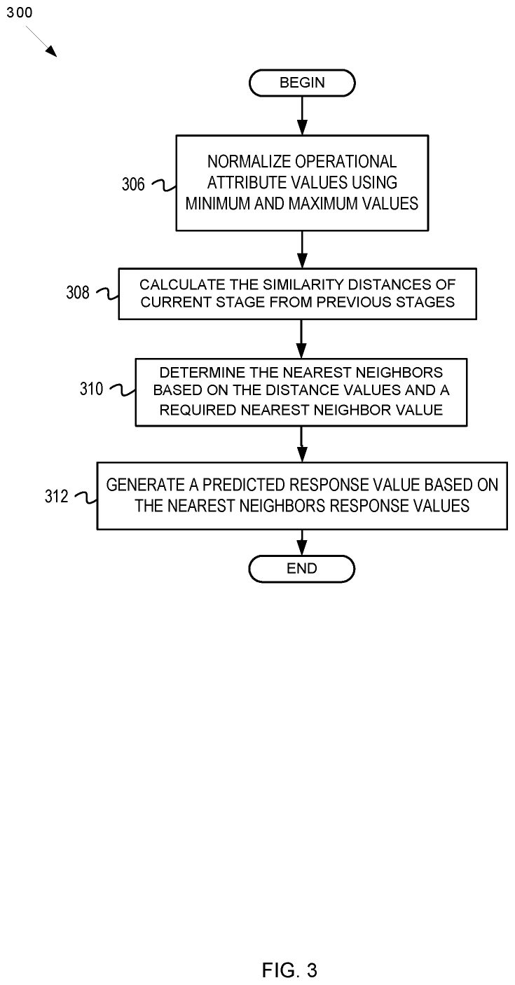

At block 214, a response is predicted for the current treatment stage using a statistics-based model based on values of one or more operational attributes of previous treatment stages. For example, the response can be predicted using a statistics-based model based on previous values of one or more operational attributes stored in an operational attribute database. Example operations for predicting a response for the current treatment stage using a statistics-based NNL model is depicted in FIG. 3, which is further described below. In some embodiments, a predicted response value can be generated with the statistics-based model based on the values of the operational attributes of previous treatment stages database and the current operational attributes for the current treatment stage. For instance, using a statistics-based NNL model, a response can be predicted based on can the values of the operational attributes of previous treatment stages that are most similar to the current treatment stage.

At block 216, one or more operational attributes for the next treatment stage are determined based on the predicted response. In some embodiments, an operational attribute for the current treatment stage can be both a preset operational attribute as well as a predicted response. Thus, the previous values of an operational attribute can be used to determine the next value of the operational attribute. For example, if the predicted response is a diverter mass and the value of the predicted response is 50 lbs. based on the previous values of the diverter mass, then 50 lbs. could be set as the diverter mass for the next treatment stage. In some embodiments, an operational attribute for the next treatment stage can be determined by a predicted response because the predicted response is within a tolerance range of a goal response. For example, if a goal response is 1700 psi for the diverter pressure response and has a tolerance of 10 psi, and a particular group of operational attributes provided a predicted diverter pressure response of 1705 psi, then the operational attributes for the next treatment stage can be set to that particular group of operational attributes. Once these operational attributes are set, they can be automatically implemented, remotely implemented, or manually implemented in real time. In some embodiments, if the goal response and the operational attributes do not match within a tolerance range, the operational attributes may be modified and the operations may start again at block 204 after the operational attributes have been modified.

At block 220, the operational attribute database is updated with the predicted response value. In one example, the predicted response value may be for a single operational attribute (e.g. flow rate, diverter mass, gel mass, sand volume, cement ratio, etc.). In other examples, the operational attribute database may be updated with multiple operational attributes, wherein some of the operational attribute values are predicted response values and other operational attribute values are based on the predicted response values.

At block 222, a determination is made of whether the next treatment stage will require a predicted response. For example, with respect to Table 1, if the current treatment stage is the fourth treatment stage and it is known that the fifth treatment stage will be the last treatment stage and thus will not require a predicted response, then the operation will end at the fourth treatment stage after having set one or more operational attribute for the fifth treatment stage. If the next treatment stage requires a predicted response, operations of the flowchart 200 return to block 204. If the next stage does not require a predicted response, operations of the flowchart 200 are complete.

Example operations for predicting a response to a wellbore treatment operation using statistics-based modeling are now described. FIG. 3 depicts a flowchart of operations for statistics-based modeling of wellbore treatment operations, according to some embodiments. Operations of a flowchart 300 of FIG. 3 can be performed by software, firmware, hardware or a combination thereof. For example, with reference to FIG. 10 (further described below), a processor in a computer device located at the surface can execute instructions to perform operations of the flowchart 300. Additionally, operations of the flowchart 300 are described with reference to predicting a response based on values of one operational attribute. However, operations of the flowchart 300 can incorporate values from multiple operational attributes. Operations of the flowchart 300 begin at block 306.

At block 306, values of the operational attribute are normalized using minimum and maximum values. Normalization can re-scale all of the values across multiple stages such that the values of the operational attribute fall between a pre-determined range. In some embodiments, a normalized operational attribute value X_{normalized} can be calculated from the non-normalized operational attribute value X based on the maximum and the minimum in the statistical range, Xₘₐₓ and Xₘᵢₙ, respectively. With these values, a linear normalization strategy can be implemented as in the form shown in Equation 1:

$${X}_{normalized} = \frac{X - {X}_{min}}{{X}_{max} - {X}_{min}} \qquad ( 1 )$$

For example, with reference to Table 1, during operations to predict the response of the fourth stage, the operational attribute “flow rate” would have three previous values: 0.01 bpm, 0.015 bpm, and 0.037 bpm. From this list, the minimum operational attribute value is 0.01 bpm and the maximum operational attribute value is 0.037 bpm. Using Equation 1, the normalized operational attribute values would be 0.00, 0.19, and 1.00, respectively. Likewise, the “flow rate” of the fourth stage, 0.03 bpm, would be converted to approximately 0.74. With further respect to Table 1, the same operation can be applied to the other parameters “well pressure” and “actual diverted added.” These results can be seen in Table 2:

TABLE 2

| | Normalized | Normalized | Normalized |
|---|---|---|---|
| | Well | Actual | Flow |
| Treatment | Pressure | Diverter Added | Rate |
| stage | (psi) | (lbs) | (bpm) |
| 1 | 0.17 | 0.570 | 0.00 |
| 2 | 1.00 | 0.185 | 0.19 |
| 3 | 0.00 | 1.00 | 1.00 |
| 4 | 0.33 | 0.7407 | 0.74 |

In some embodiments, other data pre-processing operations can be applied to values of the operational attribute. For example, a minimum outlier threshold and maximum outlier threshold can be used to flag values less than the minimum outlier threshold or values greater than the maximum outlier threshold. In other embodiments, non-linear normalization strategies such as root normalization or logarithmic normalization can be applied.

At block 308, similarity distances of the current treatment stage from the previous treatment stages are determined. A similarity distance value D can be assigned to each previous treatment stage to quantify the similarity of data in each of the previous treatment stages compared to the current treatment stage. For example, for the i-th stage, a similarity distance Dᵢ can be calculated by performing a Euclidean distance calculation between each of the previous treatment stages and the current treatment stage based on their preset operational attributes. This operation is shown in Equation 2 below, wherein N_{variables} is the total number of preset operational attributes, j is an index value for each preset operational attribute, Xi,ⱼ is the j-th preset operational attribute for the i-th stage, and X_{current,j} is the j-th preset operational attribute for the current treatment stage:

$${D}_{i} = \sqrt{{\sum }_{j = 1}^{{N}_{variables}} {( {X}_{current , j} - {X}_{i , j} )}^{2}} \qquad ( 2 )$$

For example, with respect to Table 2, the Euclidean distance of the current treatment stage (i.e. the fourth stage) from the first treatment stage can be found by implementing Equation 2 and arriving at the equation \sqrt{(167−333)²+(0.570−0.677)²+(0−0.741)²}=0.767. These same operations can be performed on each of the treatment stages and are represented in Table 2, resulting in the Euclidean distance values shown in Table 3.

TABLE 3

| | | Diverter Pressure |
|---|---|---|
| Treatment | Euclidean | Response |
| Stage | Distance | (Psi) |
| 1 | 0.767 | 500 |
| 2 | 1.101 | 1500 |
| 3 | 0.531 | 2000 |

At block 310, the nearest neighbors are determined, based on the distance values and a requisite number of nearest neighbors. The nearest neighbors can be determined by finding the stages with the lowest similarity distances until the number of found stages is equal to a requisite number of nearest neighbors. For example, with reference to Table 3, if the requisite nearest neighbor value is 2, then two nearest neighbors will be selected: the first treatment stage and the third treatment stage.

At block 312, a predicted response value is generate based on the nearest neighbor response values. The predicted response value can be calculated by weighting the predicted response by the similarity distances. One method of determining the predicted response can be to use Equation 3, where kstage is the requisite number of nearest neighbors, i is an index value representing the stage, and Yᵢ represents the response value at the i-th stage:

$$Y = \frac{{\sum }_{i = 1}^{i = kstage} \frac{{Y}_{i}}{{D}_{i}^{2}}}{{\sum }_{i = 1}^{i = kstage} \frac{1}{{D}_{i}^{2}}} \qquad ( 3 )$$

For example, with reference to Table 3, using Euclidean distances as the similarity distance values and noting that the first stage and third stage are the stages found to be the nearest neighbor, the predicted response value can be calculated as shown in Equation 4:

$$Y = \frac{\frac{600 psi}{.76 {7}^{2}} + \frac{2200 psi}{.53 {1}^{2}}}{\frac{1}{.76 {7}^{2}} + \frac{1}{.53 {1}^{2}}} = 1681 psi \qquad ( 4 )$$

Operations of the flowchart 300 are complete.

The flowcharts are provided to aid in understanding the illustrations and are not to be used to limit scope of the claims. The flowcharts depict example operations that can vary within the scope of the claims. Additional operations may be performed; fewer operations may be performed; the operations may be performed in parallel; and the operations may be performed in a different order. For example, the operations depicted in blocks 206, 208, and 210 can be performed in parallel or concurrently. It will be understood that each block of the flowchart illustrations and/or block diagrams, and combinations of blocks in the flowchart illustrations and/or block diagrams, can be implemented by program code. The program code may be provided to a processor of a general purpose computer, special purpose computer, or other programmable machine or apparatus.

### Example Physics-Based Model

An example physics-based model is now described. A physics-based model applies a set of equations and boundary conditions which are used to model physical phenomena. This model can be used to describe the fluid flow and concentration evolution within an open-hole completion system over three geometric domains: wellbore, reservoir, and fluid junction zones.

In the wellbore domain, the dimensionless fluid mass and momentum conservations for a one-dimensional Cartesian coordinate system can be described as follows:

$$\begin{matrix}\frac{d u}{d x} = 0 & ( 5 ) \\ \frac{d u}{d t} + \frac{d {u}^{2}}{d x} + \frac{d p}{d x} + \frac{{f}_{f}}{π} {u}^{2} = \frac{1}{Re} \frac{{d}^{2} u}{{dx}^{2}} - \frac{1}{{Fr}^{2}} cos θ & ( 6 ) \\ \frac{d ( C )}{d t} + \frac{d ( C {u}_{f} )}{d y} = {M}_{W} & ( 7 )\end{matrix}$$

Where M_{W} is fluid mass loss at the perforations, u is fluid velocity, p is the pressure, x is position along the one-dimensional wellbore, y is the position along the fracture, C is the concentration of diverter/proppant in the wellbore fluid, and the friction for f_{f}, Reynolds number Re, and Froude number Fr are modeled as:

$$\begin{matrix}{f}_{f} = \{ \begin{matrix}\frac{64}{R e} & R e \leq 2300 \\ . 079 R {e}^{- .25} & R e > 2300\end{matrix} & ( 8 ) \\ Re = \frac{ρ {u}_{inlet} D}{μ} & ( 9 ) \\ Fr = \frac{{u}_{inlet}}{\sqrt{g D}} & ( 10 )\end{matrix}$$

Where uᵢₙₗₑₜ is the fluid velocity at the wellbore inlet, ρ is the wellbore fluid density, μ is the wellbore fluid viscosity, g is gravitational acceleration, D is the wellbore diameter

In the fracture domain, the dimensionless fluid mass and momentum conservation equations are:

$$\begin{matrix}\frac{d ( {ρ}_{f} )}{d t} + \frac{d ( ρ {u}_{f} )}{d y} = {M}_{f} & ( 11 ) \\ {u}_{f} = - D a \frac{d p}{d y} & ( 12 ) \\ \frac{d ( C )}{d t} + \frac{d ( C {u}_{f} )}{d y} = 0 & ( 13 )\end{matrix}$$

Where ρ_{f} is fracture fluid density, μ_{f} is fracture fluid viscosity, y is distance along the fracture, t is time, M_{f} is fluid mass lost in the fracture, and Da is the Darcy Number, defined as:

$$D a = \frac{K}{{D}^{2}} R e \qquad ( 14 )$$

Where K is permeability, defined initially as:

$$K = \frac{w}{12} \qquad ( 15 )$$

Where w is the fracture width.

In certain embodiments, connection equations are applied to each of a set of connection points to properly connect flow and concentration of diverter in the wellbore and the fracture. Connection equations suitable for certain embodiments of the present disclosure include, but are not limited to mass conservation, pressure continuity, and Reynolds law to model the velocity u_{f} at every junction point except the last junction point. Specifically, at any junction point other than the last junction point, the connection equations may be as follows:

$$\begin{matrix}{u}_{w , i n} - {u}_{w , out} = \frac{2 h w}{π {R}_{w}^{2}} {u}_{f} & ( 16 ) \\ {p}_{w} = {p}_{f} & ( 17 ) \\ {u}_{f} = - D a \frac{d p}{d y} & ( 18 ) \\ {C}_{w} = {C}_{f} & ( 19 )\end{matrix}$$

Where u_{w,in} is wellbore fluid velocity into the junction and u_{w,out} is wellbore fluid velocity out of the junction, h is the fracture height, C_{W} is the concentration of the diverter/proppant in the wellbore, C_{f} is the concentration of the diverter/proppant in the fracture, p_{w} is the wellbore pressure, p_{f} is the fracture pressure, and R_{W} is the flow resistance.

The diversion flow model may comprise a width-pressure model to determine the width of the fracture (w). In some embodiments, the width-pressure model may be described as:

$$w = \frac{2 ( 1 - {v}^{2} ) h}{E} ( P - {P}_{closure} ) \qquad ( 20 )$$

Where E is the Young's modulus, v is the Poisson's ratio, and P_{closure} is the closure pressure.

The diversion flow model may account for the effect of the diverter on flow. For example, in certain embodiments, the presence of a diverter may cause a reduction in permeability due to, for example, an increase in skin. The diversion flow model may couple permeability reduction due to the presence of a diverter with flow and track the concentration of the diverter. In some embodiments, diverter effects on flow are modeled as:

$${u}_{f} = - \frac{1}{\frac{μlog ( {R}_{w} + δ ) / {R}_{w}}{k 2 π {L}_{perf}} + \frac{μ Δ R}{k w h}} \frac{d p}{d y} \qquad ( 21 )$$

Where δ is the additional resistance to flow caused by the diverter, L_{perf} is the length of the perforation, ΔR is the change in fracture radius, and k is permeability, which may be computed according to equations (22) and (23):

$$\begin{matrix}k = \frac{{λ}^{2} {D}_{p}^{2} {φ}^{3}}{180 {( 1 - φ )}^{3}} & ( 22 ) \\ φ = \frac{{V}_{performation} - {M}_{j} {ρ}_{particles}}{{V}_{perforation}} & ( 23 )\end{matrix}$$

Where ϕ is porosity, Dₚ is the particle diameter, λ is the particle sphericity, V_{perforation} is the volume of the perforation, and ρ_{particles} is the particle density.

In some embodiments, the diversion flow model captures the effect of the diverter on fluid flow by accounting for the reduction in permeability caused by the diverter based, at least in part, on equation (21).

At the last connection point, all of the remaining fluid may be assumed to leave the domain. The mass conservation and Reynolds law to model the pressure may be as follows:

$$\begin{matrix}{u}_{f} = \frac{2 h w}{π {R}_{w}^{2}} {u}_{w} & ( 24 ) \\ \frac{d p}{d y} = - \frac{1}{D a} {u}_{f} & ( 25 )\end{matrix}$$

Boundary conditions and initial conditions are needed to close the system of Equations 5-25. In some embodiments, boundary conditions of the diversion flow model include, but are not limited to:

$$\begin{matrix}u {\vert}_{x = 0} = {u}_{inlet} & ( 26 ) \\ \frac{d ( u )}{d y} {\vert}_{y = {L}_{f}} = 0 & ( 27 ) \\ P {\vert}_{y = {L}_{f}} = {P}_{e} & ( 28 ) \\ y {\vert}_{x = L} = 0 & ( 29 )\end{matrix}$$

Where L_{f} is the fracture effective length, L is the wellbore length, and pₑ is the reservoir pressure.

In some embodiments, the diversion flow model may be solved using a numerical solving method, such as a finite difference approach. In a typical finite difference approach, the computational geometry domain may be discretely represented by sequence of connected points called “nodes” or “grid elements” or “a mesh.” These nodes can represent locations in one, two, or three dimensions. These nodes need not be uniformly distributed in the computational domain. Some numerical schemes can be optimized or otherwise improved by distributing the nodes in the relevant domain. In certain embodiments, the system of equations for the diversion flow model may be numerically solved by using a first-order implicit method for time, a spatially second-order upwind scheme for convective terms, and a second-order central scheme for second derivatives with the velocity and pressure staggered at discretization nodes. In certain embodiments, equation (18) may be used everywhere in the fracture domain except at the first grid element, where skin may need to be accounted for due to the presence of the diverter. Equation (21) may be used instead of (18) at the first grid element at each fracture layer.

In some embodiments, the diversion flow model may be solved implicitly. The diversion flow model of the present disclosure may be solved using any suitable numerical solving method. In certain embodiments, the system of equations (5) through (29) may be numerically solved by using a first-order implicit method for time, a spatially second-order upwind scheme for convective terms, and a second-order central scheme for second derivatives with the velocity and pressure staggered at discretization nodes.

In certain embodiments, the diversion flow model may provide one or more predicted response values. Such predicted response values may include, but are not limited to the wellbore system flow distribution, the wellbore system pressure distribution, the formation stress field, any other parameter related to the wellbore or treatment operation, and any combination thereof.

For example, in certain embodiments, the wellbore system pressure distribution and wellbore system flow distribution may be determined based, at least in part, on the one or more preset operational attributes and the diversion flow model. In certain embodiments, a treatment operation is performed based, at least in part, on at least one of the wellbore system pressure distribution and the wellbore system flow distribution.

### Example Multi-Well Nearest Neighbor Learning Model

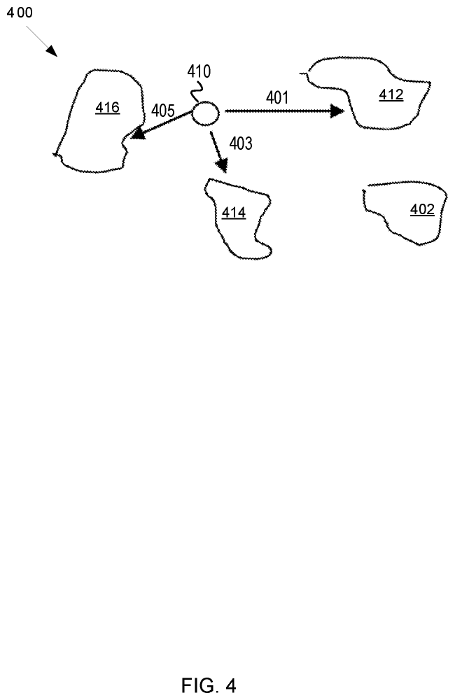

In some embodiments, statistics-based modeling can incorporate operational attributes from other wells. To illustrate, FIG. 4 depicts an example Nearest Neighbor Learning (NNL) regional model applicable in a multi-well statistics-based modeling of wellbore treatment operations, according to some embodiments. A multi-well diagram 400 depicts a current well 410 that is in geographic proximity to each of a formation 412, a formation 414, and a formation 416. The distance from the current well 410 to the formation 412 is represented by the longest line 401. The distance from the current well 410 to the formation 414 is represented by the shortest line 403. The distance from the current well 410 to the formation 416 is represented by the middle-length line 405. In this example, the longest line 401 is also the geographic length threshold and wells that are analyzed in the NNL regional model are within the geographic length threshold. Thus, a well in the formation 402 has a distance from the current well 410 that exceeds the geographic length threshold, and thus will not be included in the database of values to be used during operations with the current well 410.

At each of the formations 412, 414, and 416, operational attributes of treatment operations at a well can be collected. For example, the operational attribute database can be augmented to include data from the other well sites at the formations 412, 414, and 416, with an additional parameter known as a well similarity weight to represent the similarity distance between two different wells. In one example, the well similarity weights between each of the wells at formations 412, 414, and 416 and the current well 410 are different. In some embodiments, the lengths of the lines 401, 403, and 405 can be used in part to determine the well similarity weights. Similarity between formation geology can also be used in part to determine the well similarity weights. Additionally, the value of other operational attributes shared between wells can be used to determine well similarity weights.

A combined predicted response Y can be determined based on the well similarity weights and the individual predicted responses of each well. This relationship is shown in Equation 30, where kwells is the number of wells considered in the current operation, D_{iwell} is the well similarity weight for a particular well, and Y_{iwell} is a predicted response value for that same particular well:

$$Y = \frac{{\sum }_{iwell = 1}^{iwell = k w e l l s} \frac{{Y}_{i well}}{{D}_{i well}^{2}}}{{\sum }_{i well = 1}^{i well = kwells} \frac{1}{{D}_{iwell}^{2}}} \qquad ( 30 )$$

In some embodiments, each well similarity weight can be normalized to linearly range from a greater value such as 1.0 at the geographic length threshold to a lesser value such as 0.1 at the current well. For example, a combined operational attribute database based on operational attributes from the current well 410 and other wells can be arranged as shown in Table 4, wherein the current well 410 has the same operational attributes as shown in Tables 2 and 3, and wherein 412-1, 412-2, and 412-3 are the first, second, and third treatment stages from the well in formation 412, and wherein 414-1, 414-2, and 414-3 are the first, second, and third treatment stages from the well in formation 414, and wherein 416-1, 416-2, and 416-3 are the first, second, and third treatment stages from the well in formation 416:

TABLE 4

| | Original | | Diverter Pressure |
|---|---|---|---|
| Treatment | Euclidean | Proximity | Response |
| Stage | Distance | Weight | (psi) |
| 1 | 0.767 | 0.10 | 600 |
| 2 | 1.101 | 0.10 | 1500 |
| 3 | 0.531 | 0.10 | 2200 |
| 412-1 | 0.140 | 1.00 | 1000 |
| 412-2 | .250 | 1.00 | 1250 |
| 412-3 | .500 | 1.00 | 1800 |
| 414-1 | .050 | 0.25 | 1000 |
| 414-2 | .500 | 0.25 | 1400 |
| 414-3 | .300 | 0.25 | 1900 |
| 416-1 | .900 | 0.50 | 1000 |
| 416-2 | .300 | 0.50 | 1600 |
| 416-3 | .600 | 0.50 | 2100 |

With respect to Table 4, the combined predicted response value for the diverter pressure response can be determined by calculating the predicted response value for the current well 410 and each of the other wells using Equation 3. The predicted response value for the current well 410 is already provided by Equation 4. Applying Equation 3 to each of the individual wells results in the predicted responses Y₄₁₂, Y₄₁₄, and Y₄₁₆, representing the predicted diverter pressure response for each of the wells at the formations 412, 414, and 416, respectively.

This calculation is depicted in Equations 31-33:

$$\begin{matrix}{Y}_{412} = \frac{\frac{1000 psi}{.14 {0}^{2}} + \frac{1250 psi}{.25 {0}^{2}}}{\frac{1}{.14 {0}^{2}} + \frac{1}{.25 {0}^{2}}} = 1059 psi & ( 31 ) \\ {Y}_{414} = \frac{\frac{1000 psi}{.05 {0}^{2}} + \frac{1400 psi}{.30 {0}^{2}}}{\frac{1}{0.05 {0}^{2}} + \frac{1}{0.30 {0}^{2}}} = 1011 psi & ( 32 ) \\ {Y}_{416} = \frac{\frac{1600 psi}{.30 {0}^{2}} + \frac{2100 psi}{.60 {0}^{2}}}{\frac{1}{0.30 {0}^{2}} + \frac{1}{0.60 {0}^{2}}} = 1700 psi & ( 33 )\end{matrix}$$

Equation 30 can then be applied by using the predicted response values calculated in Equations 4 and 31-33, as shown in Equation (34):

$$Y = \frac{\frac{1681 psi}{{.10}^{2}} + \frac{1059 psi}{1.0 {0}^{2}} + \frac{1011 psi}{{.25}^{2}} + \frac{1700 psi}{{.50}^{2}}}{\frac{1}{{.10}^{2}} + \frac{1}{{1.00}^{2}} + \frac{1}{{.25}^{2}} + \frac{1}{{.50}^{2}}} = 1 psi \qquad ( 34 )$$

Example Graph of Predicted v. Actual Response Values

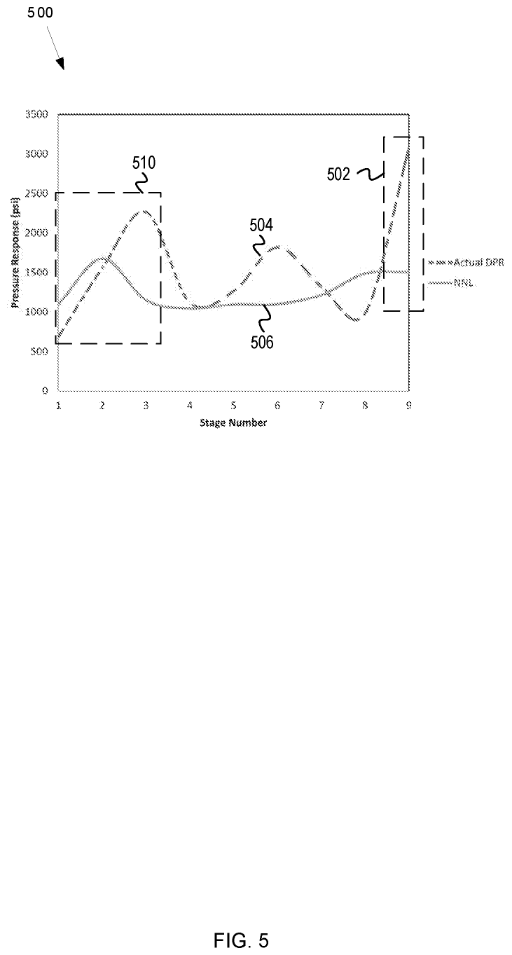

FIG. 5 depicts an example graph illustrating a normalized comparison of responses over multiple stages between predicted response values using NNL modeling and actual response values, according to some embodiments. A plot 500 includes a dashed line 504, a solid line 506, an x-axis, and a y-axis. The dashed line 504 represents the actual downhole pressure response and the solid line 506 represents the NNL prediction. The y-axis represents the pressure response in the units “psi.” The x-axis represents the stage number of the treatment operation. Region 510 depicts the first three treatment stages of the operation. As shown by region 510, the NNL model can be inaccurate when a minimum stage threshold is not met. For example, with reference to FIG. 2, at block 208 of the operation, if the minimum stage threshold is 3, the first, second, and third stage treatment stages would not be greater than the minimum stage threshold, and thus a physics-based model would be used to predict the pressure response. Region 502 depicts the predicted response value using a NNL method when at least one of the values of the operational attributes of the current treatment stage is outside the statistical range. With further reference to FIG. 2, at block 210, the statistics-based modeling criteria that all current parameter values be within the statistical range would not be satisfied at the ninth stage. Thus, region 502 also represents a region where the physics-based model would be used to generate a predicted response value.

### Example System for Wellbore Treatment or Stimulation

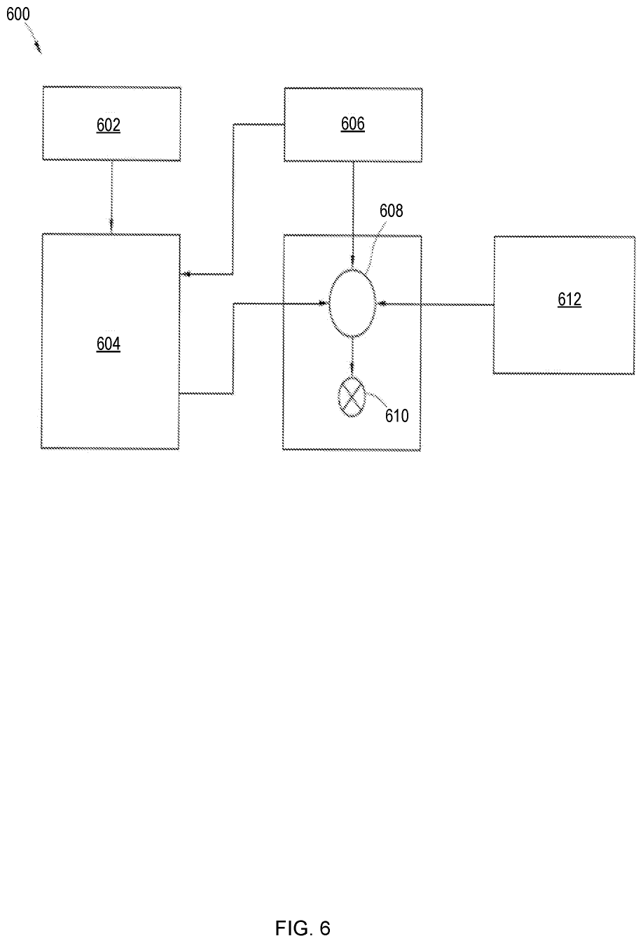

Some embodiments of the methods disclosed herein may directly or indirectly affect one or more components or pieces of equipment associated with the preparation, delivery, recapture, recycling, reuse, and/or disposal of wellbore compositions. For instance, FIG. 6 depicts an example wellbore treatment or stimulation system, according to some embodiments.

FIG. 6 depicts an example wellbore treatment or stimulation system, according to some embodiments. The disclosed methods may directly or indirectly affect one or more components or pieces of equipment associated with the system 600. In some embodiments, the system 600 includes a fluid producing apparatus 604, a fluid source 606, an optional proppant source 612, and a pump and blender system 608 and resides at the surface at a well site where a well 610 is located. The fluid can be a fluid for ready use in a fracture stimulation treatment or acidizing treatment of the well 610. In other embodiments, the fluid producing apparatus 604 may be omitted and the fluid sourced directly from the fluid source 606.

The optional proppant source 612 can include a proppant for combination with a fracturing fluid. However, in some embodiments, the optional proppant source 612 may be omitted such that the treatment fluid formed using the fluid producing apparatus 604 does not include a significant amount of solid materials/particulates. The system 600 may also include an additive source 602 that provides one or more additives (e.g., diverters, bridging agents, gelling agents, weighting agents, and/or other optional additives) to alter the properties of the fluid. For example, the additive source 602 can be included to reduce pumping friction, to reduce or eliminate the fluid's reaction to the geological formation in which the well is formed, to operate as surfactants, and/or to serve other functions. In some embodiments, the diverter and bridging agent of the present disclosure may be introduced into a fluid via additive source 602.

The pump and blender system 608 may receive the fluid and combine it with other components, including proppant from the optional proppant source 612 and/or additional components from the additives source 602. In certain embodiments, the resulting mixture may be pumped down the well 610 under a pressure sufficient to create or enhance one or more fractures in a subterranean zone, for example, to stimulate production of fluids from the zone. In certain embodiments, the resulting mixture may be pumped down the well 610 at a pressure suitable for an acidizing operation. Notably, in certain instances, the fluid producing apparatus 604, the fluid source 606, and/or optional proppant source 612 may be equipped with one or more metering devices or sensors (not shown) to control and/or measure the flow of fluids, proppants, diverts, bridging agents, and/or other compositions to the pump and blender system 608. In certain embodiments, the metering devices may permit the pump and blender system 608 to source from one, some or all of the different sources at a given time, and may facilitate the preparation of fluids in accordance with the present disclosure using continuous mixing or “on-the-fly” methods. Thus, for example, the pump and blender system 608 can provide just fluid into the well at some times, just additives at other times, and combinations of those components at yet other times.

While not specifically illustrated herein, the disclosed methods and systems may also directly or indirectly affect any transport or delivery equipment used to convey wellbore compositions to the pump and blender system 608 such as, for example, any transport vessels, conduits, pipelines, trucks, tubulars, and/or pipes used to fluidically move compositions from one location to another, any pumps, compressors, or motors used to drive the compositions into motion, any valves or related joints used to regulate the pressure or flow rate of the compositions, and any sensors (e.g., pressure and temperature), gauges, and/or combinations thereof, and the like.

### Example Wellbore Treatment or Stimulation Applications

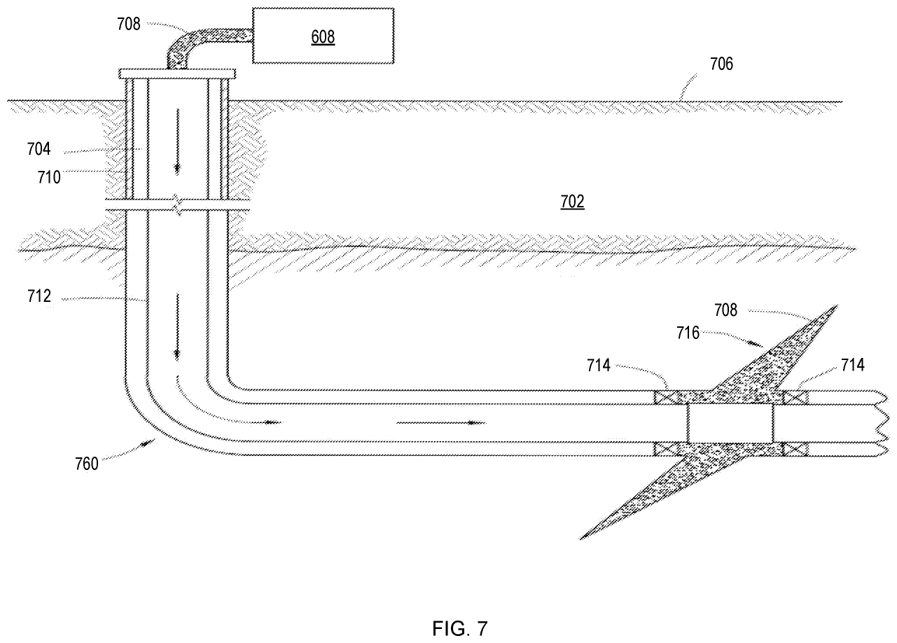

Various example wellbore treatment or stimulation applications are now described with reference to FIGS. 7-9.

FIG. 7 depicts an example fracturing operation being performed in a subterranean formation, according to some embodiments. FIG. 7 depicts a well 760 during a fracturing operation in a portion of a subterranean formation 702 surrounding a wellbore 704. The wellbore 704 extends from a surface 706, and a fracturing fluid 708 is applied to a portion of the subterranean formation 702 surrounding the horizontal portion of the wellbore 704. Although shown as vertical deviating to horizontal, the wellbore 704 may include horizontal, vertical, slant, curved, and other types of wellbore 704 geometries and orientations, and the fracturing treatment may be applied to a subterranean zone surrounding any portion of the wellbore 704. The wellbore 704 can include a casing 710 that is cemented or otherwise secured to the wellbore wall. The wellbore 704 can be uncased or include uncased sections. Perforations can be formed in the casing 710 to allow fracturing fluids and/or other materials (e.g., a diverter) to flow into the subterranean formation 702. In cased wells, perforations can be formed using shape charges, a perforating gun, hydro jetting and/or other tools.

The well 760 is shown with a work string 712 depending from the surface 706 into the wellbore 704. The pump and blender system 608 is coupled to the work string 712 to pump the fracturing fluid 708 into the wellbore 704. The work string 712 may include coiled tubing, jointed pipe, and/or other structures that allow fluid to flow into the wellbore 704. The work string 712 can include flow control devices, bypass valves, ports, and or other tools or well devices that control a flow of fluid from the interior of the work string 712 into the subterranean formation 702. For example, the work string 712 may include ports adjacent the wellbore wall to communicate the fracturing fluid 708 directly into the subterranean formation 702, and/or the work string 712 may include ports that are spaced apart from the wellbore wall to communicate the fracturing fluid 708 into an annulus in the wellbore between the work string 712 and the wellbore wall.

The work string 712 and/or the wellbore 704 may include one or more sets of packers 714 that seal the annulus between the work string 712 and wellbore 704 to define an interval of the wellbore 704 into which the fracturing fluid 708 will be pumped. FIG. 7 shows two packers 714, one defining an uphole boundary of the interval and one defining the downhole end of the interval. When the fracturing fluid 708 is introduced into wellbore 704 (e.g., the area of the wellbore 704 between packers 714) at a sufficient hydraulic pressure, one or more fractures 716 may be created in the subterranean formation 702. The proppant particulates in the fracturing fluid 708 may enter the fractures 716 as shown, or may plug or seal off fractures 716 to reduce or prevent the flow of additional fluid into those areas.

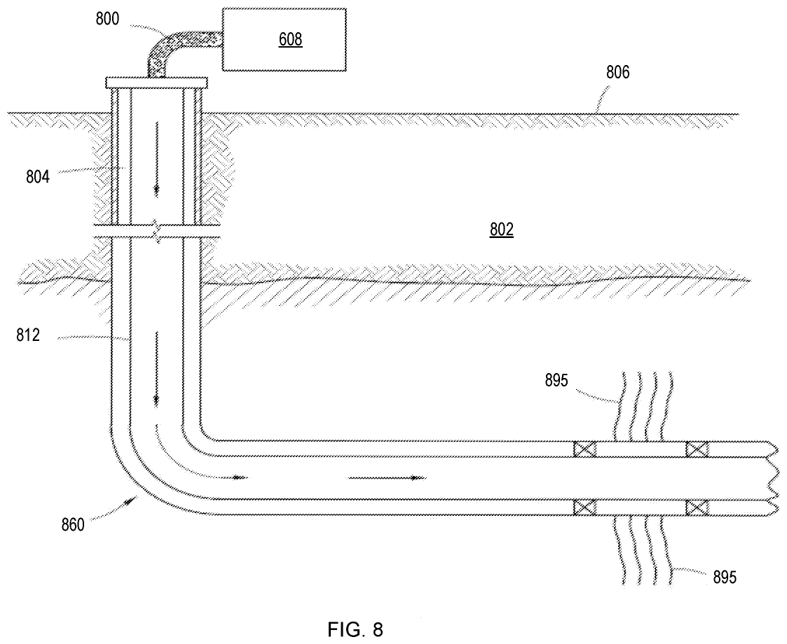

FIG. 8 depicts an example acidizing operation being performed in a subterranean formation. In FIG. 8, a well 860 is shown during an acidizing operation according to certain embodiments of the present disclosure in a portion of a subterranean formation 802 surrounding a wellbore 804. The subterranean formation 802 may comprise acid-soluble components. The subterranean formation 802 may be a carbonate formation, sandstone formation, mixed carbonate-sandstone formation, or any other subterranean formation suitable for an acidizing treatment. The wellbore 804 can include a casing that is cemented or otherwise secured to the wellbore wall. The wellbore 804 can be uncased or include uncased sections. The pump and blender system 608 is coupled to a work string 812 to pump an acidizing fluid 800 into the wellbore 804.

In some embodiments, the work string 812 may include ports adjacent the wellbore wall to communicate the acidizing fluid 800 directly into the subterranean formation 802, and/or the work string 812 may include ports that are spaced apart from the wellbore wall to communicate the acidizing fluid 800 into an annulus in the wellbore 804 between the work string 812 and the wellbore wall.

As shown, the wellbore 804 penetrates a portion of the subterranean formation 802, which may include a hydrocarbon-bearing reservoir. In some cases, the acidizing fluid 800 may be pumped through the work string 812 and into the portion of the subterranean formation 802.

In some embodiments, the acidizing fluid 800 may create wormholes 895 in the portion of the subterranean formation 802.

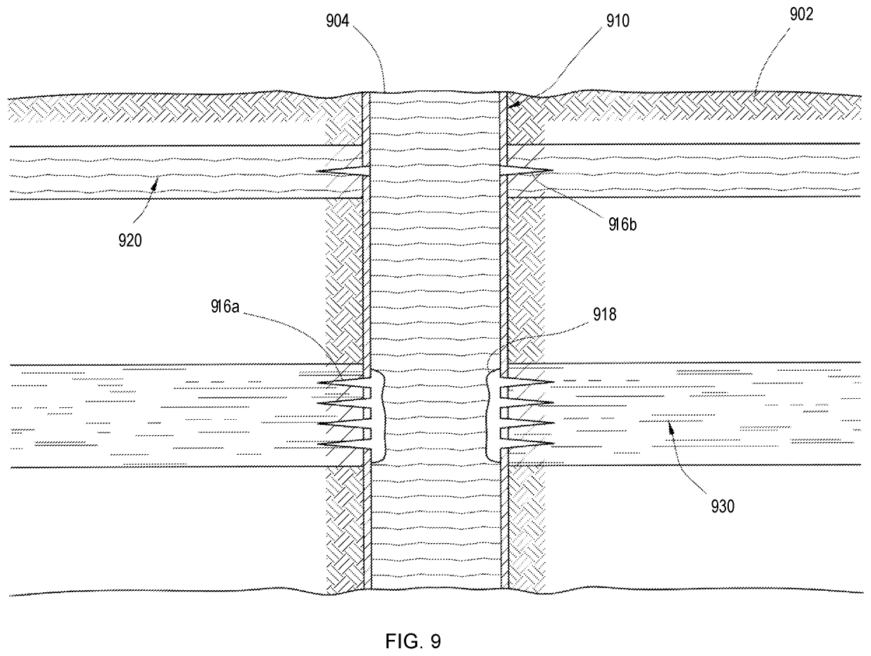

FIG. 9 depicts an example use of a diverter in a subterranean formation with multiple zones, according to some embodiments. FIG. 9 shows a side view of a subterranean formation 902 penetrated by a wellbore 904 with casing 910 placed in the wellbore 904. The wellbore 904 penetrates zone 920 and zone 930 in the subterranean formation 902, wherein the fluid flow resistance of zone 920 is higher than the fluid flow resistance of zone 930. Perforation clusters 916a and perforation clusters 916b have been created in the casing 910 to allow for fluid flow into the zones 920 and 930. In some embodiments, perforation clusters 916a, 916b may comprise one or more perforations. In certain embodiments, a perforation cluster 916a, 916b is a number of perforations shot over a finite interval, separated from another perforation cluster 916a, 916b or other clusters within the same pay zone spaced away from that cluster by another finite interval. In some embodiments, a perforation cluster 916a, 916b may be characterized by one or more parameters, including, but not limited to perforation length, the total number of perforations, the perforation radius, and the spacing between clusters.

In certain embodiments, a treatment fluid comprising a diverter and/or a bridging agent may be introduced into at least a portion of the perforations 912 within the zone 930 or adjacent to a least a portion of zone 930 of the subterranean formation 902 using one or more pumps.

Once introduced into the wellbore 904, the diverter and/or bridging agent may form a bridge 918 to plug or partially plug zone 930. The treatment fluid may then be diverted by the bridge 918 to the less permeable zone 920 of the subterranean formation 902. The treatment fluid may then create or enhance one or more fractures in the less permeable zone 920 of the subterranean formation 902.

After diverting the treatment fluid, the bridge 918 may degrade over time to at least partially unplug the zone 930. In another embodiment, this diverting procedure may be repeated with respect to each of a second, third, fourth, or more, treatment stages (not shown) to divert the treatment fluid to further less permeable zones of the subterranean formation.

### Example Computer Device

FIG. 10 depicts an example computer device, according to some embodiments. A computer device 1000 includes a processor 1001 (possibly including multiple processors, multiple cores, multiple nodes, and/or implementing multi-threading, etc.). The computer device 1000 includes a memory 1007. The memory 1007 can be system memory (e.g., one or more of cache, SRAM, DRAM, zero capacitor RAM, Twin Transistor RAM, eDRAM, EDO RAM, DDR RAM, EEPROM, NRAM, RRAM, SONOS, PRAM, etc.) or any one or more of the above already described possible realizations of machine-readable media. The computer device 1000 also includes a bus 903 (e.g., PCI, ISA, PCI-Express, HyperTransport® bus, InfiniBand® bus, NuBus, etc.) and a network interface 905 (e.g., a Fiber Channel interface, an Ethernet interface, an internet small computer system interface, SONET interface, wireless interface, etc.).

The computer device 1000 includes a wellbore treatment controller 1011. The wellbore treatment controller 1011 can perform one or more operations described above. For example, the wellbore treatment controller 1011 can select a statistics-based model or a physics-based model based on various statistics-based model criteria. The wellbore treatment controller 1011 can also predict a response to a current stage of a wellbore treatment based on the selected model. Additionally, the wellbore treatment controller 1011 can select one or more operational attributes for a next stage of the wellbore treatment based on the predicted response. In some embodiments, the wellbore treatment controller 1011 can also initiate and control the next stage based on the one or more operational attributes that have been selected.

Any one of the previously described functionalities can be partially (or entirely) implemented in hardware and/or on the processor 1001. For example, the functionality can be implemented with an application specific integrated circuit, in logic implemented in the processor 1001, in a co-processor on a peripheral device or card, etc. Further, realizations can include fewer or additional components not illustrated in FIG. 10 (e.g., video cards, audio cards, additional network interfaces, peripheral devices, etc.). The processor 1001 and the network interface 1005 are coupled to the bus 1003. Although illustrated as being coupled to the bus 1003, the memory 1007 can be coupled to the processor 1001. The computer device 1000 can be device at the surface and/or integrated into component(s) in the wellbore.

As will be appreciated, aspects of the disclosure can be embodied as a system, method or program code/instructions stored in one or more machine-readable media. Accordingly, aspects can take the form of hardware, software (including firmware, resident software, micro-code, etc.), or a combination of software and hardware aspects that can all generally be referred to herein as a “circuit,” “module” or “system.” The functionality presented as individual modules/units in the example illustrations can be organized differently in accordance with any one of platform (operating system and/or hardware), application ecosystem, interfaces, programmer preferences, programming language, administrator preferences, etc.

Any combination of one or more machine readable medium(s) can be utilized. The machine-readable medium can be a machine-readable signal medium or a machine-readable storage medium. A machine-readable storage medium can be, for example, but not limited to, a system, apparatus, or device, that employs any one of or combination of electronic, magnetic, optical, electromagnetic, infrared, or semiconductor technology to store program code. More specific examples (a non-exhaustive list) of the machine-readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a machine-readable storage medium can be any tangible medium that can contain, or store a program for use by or in connection with an instruction execution system, apparatus, or device. A machine-readable storage medium is not a machine-readable signal medium.

A machine-readable signal medium can include a propagated data signal with machine readable program code embodied therein, for example, in baseband or as part of a carrier wave. Such a propagated signal can take any of a variety of forms, including, but not limited to, electro-magnetic, optical, or any suitable combination thereof. A machine-readable signal medium can be any machine readable medium that is not a machine-readable storage medium and that can communicate, propagate, or transport a program for use by or in connection with an instruction execution system, apparatus, or device.

Program code embodied on a machine-readable medium can be transmitted using any appropriate medium, including but not limited to wireless, wireline, optical fiber cable, RF, etc., or any suitable combination of the foregoing.

Computer program code for carrying out operations for aspects of the disclosure can be written in any combination of one or more programming languages, including an object oriented programming language such as the Java® programming language, C++ or the like; a dynamic programming language such as Python; a scripting language such as Perl programming language or PowerShell script language; and conventional procedural programming languages, such as the “C” programming language or similar programming languages. The program code can execute entirely on a stand-alone machine, can execute in a distributed manner across multiple machines, and can execute on one machine while providing results and or accepting input on another machine.

The program code/instructions can also be stored in a machine-readable medium that can direct a machine to function in a particular manner, such that the instructions stored in the machine-readable medium produce an article of manufacture including instructions which implement the function/act specified in the flowchart and/or block diagram block or blocks.

Plural instances can be provided for components, operations or structures described herein as a single instance. Finally, boundaries between various components, operations and data stores are somewhat arbitrary, and particular operations are illustrated in the context of specific illustrative configurations. Other allocations of functionality are envisioned and can fall within the scope of the disclosure. In general, structures and functionality presented as separate components in the example configurations can be implemented as a combined structure or component. Similarly, structures and functionality presented as a single component can be implemented as separate components. These and other variations, modifications, additions, and improvements can fall within the scope of the disclosure.

### Example Embodiments

In some embodiments, a method comprises: determining a current value of at least one operational attribute of a current treatment stage of multiple treatment stages of a wellbore treatment operation of a current well in real time; determining whether a statistics-based model criteria has been satisfied, the statistics criteria comprising the current value of the at least one operational attribute exceeding a statistical range that comprises previous values of the at least one operational attribute of previous treatment stages of the multiple treatment stages of the current well; in response to determining that the statistics-based model criteria is not satisfied, predicting a response to the current stage of the wellbore treatment operation based on a physics-based model; in response to determining that the statistics-based model criteria is satisfied, predicting the response to the current stage of the wellbore treatment operation based on a statistics-based model; selecting, based on the predicted response, a next value of the at least one operational attribute for a next stage of the multiple treatment stages of the wellbore treatment operation; and initiating adjustment of the next stage of the wellbore treatment operation based on the next value of the at least one operational attribute.

In another embodiment, the method above, wherein the statistics-based model comprises a nearest neighbor learning model.

In another embodiment, one or more of the methods above, wherein the statistical range comprises previous values of the at least one operational attribute of previous treatment stages of the multiple treatment stages of a different well in real time, and wherein predicting the response comprises predicting the response based the statistical range.

In another embodiment, one or more of the methods above, wherein the statistics-based model criteria comprises a number of the previous treatment stages exceeding a minimum threshold.

In another embodiment, one or more of the methods above, wherein the physics-based model comprises at least one of a fluid flow model, a proppant transport model, a diverter transport model, and a junction model.

In another embodiment, one or more of the methods above, wherein the at least one operational attribute comprises a pressure in the current well, a tip pressure, a diverter mass, and a flowrate of a fluid transmitted down the current well as part of the wellbore treatment operation.

In another embodiment, one or more of the methods above, wherein the wellbore treatment operation comprises diversion, wherein the predicted response comprises a diverter pressure.

In another embodiment, one or more non-transitory machine-readable media comprises program code, the program code to: determine a current value of at least one operational attribute of a current treatment stage of multiple treatment stages of a wellbore treatment operation of a current well; determine whether a statistics-based model criteria has been satisfied, the statistics criteria comprising the current value of the at least one operational attribute exceeding a statistical range defined by previous values of the at least one operational attribute of previous treatment stages of the multiple treatment stages; in response to a determination that the statistics-based model criteria is not satisfied, predict a response to the current stage of the wellbore treatment operation based on a physics-based model; in response to a determination that the statistics-based model criteria is satisfied, predict the response to the current stage of the wellbore treatment operation based on a statistics-based model; select, based on the predicted response, a next value of the at least one operational attribute for a next stage of the multiple treatment stages of the wellbore treatment operation; and initiate adjustment of the next stage of the wellbore treatment operation based on the next value of the at least one operational attribute.

In another embodiment, one or of the more non-transitory machine-readable media above, wherein the statistics-based model comprises a near neighbor learning model.

In another embodiment, one or of the more non-transitory machine-readable media above, wherein the statistical range comprises previous values of the at least one operational attribute of previous treatment stages of the multiple treatment stages of a different well, and wherein the program code to predict the response comprises program code to predict the response based the statistical range.

In another embodiment, one or of the more non-transitory machine-readable media above, wherein the statistics-based model criteria comprises a number of the previous treatment stages exceeding a minimum threshold.

In another embodiment, one or of the more non-transitory machine-readable media above, wherein the physics-based model comprises at least one of a fluid flow model, a proppant transport model, a diverter transport model, and a junction model.

In another embodiment, one or of the more non-transitory machine-readable media above, wherein the at least one operational attribute comprises a pressure in the current well, a tip pressure, a diverter mass, and a flowrate of a fluid transmitted down the current well as part of the wellbore treatment operation.

In another embodiment, one or of the more non-transitory machine-readable media above, wherein the wellbore treatment operation comprises diversion, wherein the predicted response comprises a diverter pressure.

In another embodiment, a system comprises: a pump to pump a fluid down a current well as part of a wellbore treatment operation; a processor; and a machine-readable medium having program code executable by the processor to cause the processor to, determine a current value of at least one operational attribute of a current treatment stage of multiple treatment stages of the wellbore treatment operation; determine whether a statistics-based model criteria has been satisfied, the statistics criteria comprising the current value of the at least one operational attribute exceeding a statistical range defined by previous values of the at least one operational attribute of previous treatment stages of the multiple treatment stages; in response to a determination that the statistics-based model criteria is not satisfied, predict a response to the current stage of the wellbore treatment operation based on a physics-based model; in response to a determination that the statistics-based model criteria is satisfied, predict the response to the current stage of the wellbore treatment operation based on a statistics-based model; select, based on the predicted response, a next value of the at least one operational attribute for a next stage of the multiple treatment stages of the wellbore treatment operation; and initiate adjustment of the pump in the next stage of the wellbore treatment operation based on the next value of the at least one operational attribute.

In another embodiment, one or of the system above, wherein the statistics-based model comprises a near neighbor learning model.

In another embodiment, one or of the system above, wherein the statistical range comprises previous values of the at least one operational attribute of previous treatment stages of the multiple treatment stages of a different well, and wherein the program code to cause the processor to predict the response comprises program code to cause the processor to predict the response based the statistical range.

In another embodiment, one or of the system above, wherein the statistics-based model criteria comprises a number of the previous treatment stages exceeding a minimum threshold.

In another embodiment, one or of the system above, wherein the physics-based model comprises at least one of a fluid flow model, a proppant transport model, a diverter transport model, and a junction model.

In another embodiment, one or of the system above, wherein the at least one operational attribute comprises a pressure in the current well, a tip pressure, a diverter mass, and a flowrate of a fluid transmitted down the current well as part of the wellbore treatment operation.

Use of the phrase “at least one of” preceding a list with the conjunction “and” should not be treated as an exclusive list and should not be construed as a list of categories with one item from each category, unless specifically stated otherwise. A clause that recites “at least one of A, B, and C” can be infringed with only one of the listed items, multiple of the listed items, and one or more of the items in the list and another item not listed.

What is claimed is:

1. A method comprising:
determining a current value of at least one operational attribute of a current treatment stage of multiple treatment stages of a wellbore treatment operation of a current well in real time;
determining whether a statistics-based model criteria has been satisfied, the statistics criteria comprising the current value of the at least one operational attribute exceeding a statistical range that comprises previous values of the at least one operational attribute of previous treatment stages of the multiple treatment stages of the current well;
in response to determining that the statistics-based model criteria is not satisfied, predicting a response to the current stage of the wellbore treatment operation based on a physics-based model;
in response to determining that the statistics-based model criteria is satisfied, predicting the response to the current stage of the wellbore treatment operation based on a statistics-based model;
selecting, based on the predicted response, a next value of the at least one operational attribute for a next stage of the multiple treatment stages of the wellbore treatment operation; and
initiating adjustment of the next stage of the wellbore treatment operation based on the next value of the at least one operational attribute.

2. The method of claim 1, wherein the statistics-based model comprises a nearest neighbor learning model.

3. The method of claim 1, wherein the statistical range comprises previous values of the at least one operational attribute of previous treatment stages of the multiple treatment stages of a different well.

4. The method of claim 1, wherein the statistics-based model criteria comprises a number of the previous treatment stages exceeding a minimum threshold.

5. The method of claim 1, wherein the physics-based model comprises at least one of a fluid flow model, a proppant transport model, a diverter transport model, and a junction model.

6. The method of claim 1, wherein the at least one operational attribute comprises a pressure in the current well, a tip pressure, a diverter mass, and a flowrate of a fluid transmitted down the current well as part of the wellbore treatment operation.

7. The method of claim 1, wherein the wellbore treatment operation comprises diversion, wherein the predicted response comprises a diverter pressure.

8. One or more non-transitory machine-readable media comprising program code, the program code to:
determine a current value of at least one operational attribute of a current treatment stage of multiple treatment stages of a wellbore treatment operation of a current well;
determine whether a statistics-based model criteria has been satisfied, the statistics criteria comprising the current value of the at least one operational attribute exceeding a statistical range defined by previous values of the at least one operational attribute of previous treatment stages of the multiple treatment stages;
in response to a determination that the statistics-based model criteria is not satisfied, predict a response to the current stage of the wellbore treatment operation based on a physics-based model;
in response to a determination that the statistics-based model criteria is satisfied, predict the response to the current stage of the wellbore treatment operation based on a statistics-based model;
select, based on the predicted response, a next value of the at least one operational attribute for a next stage of the multiple treatment stages of the wellbore treatment operation; and
initiate adjustment of the next stage of the wellbore treatment operation based on the next value of the at least one operational attribute.

9. The one or more non-transitory machine-readable media of claim 8, wherein the statistics-based model comprises a near neighbor learning model.

10. The one or more non-transitory machine-readable media of claim 8, wherein the statistical range comprises previous values of the at least one operational attribute of previous treatment stages of the multiple treatment stages of a different well.

11. The one or more non-transitory machine-readable media of claim 8, wherein the statistics-based model criteria comprises a number of the previous treatment stages exceeding a minimum threshold.

12. The one or more non-transitory machine-readable media of claim 8, wherein the physics-based model comprises at least one of a fluid flow model, a proppant transport model, a diverter transport model, and a junction model.

13. The one or more non-transitory machine-readable media of claim 8, wherein the at least one operational attribute comprises a pressure in the current well, a tip pressure, a diverter mass, and a flowrate of a fluid transmitted down the current well as part of the wellbore treatment operation.

14. The one or more non-transitory machine-readable media of claim 8, wherein the wellbore treatment operation comprises diversion, wherein the predicted response comprises a diverter pressure.

15. A system comprising:
a pump to pump a fluid down a current well as part of a wellbore treatment operation;
a processor; and
a machine-readable medium having program code executable by the processor to cause the processor to,
determine a current value of at least one operational attribute of a current treatment stage of multiple treatment stages of the wellbore treatment operation;
determine whether a statistics-based model criteria has been satisfied, the statistics criteria comprising the current value of the at least one operational attribute exceeding a statistical range defined by previous values of the at least one operational attribute of previous treatment stages of the multiple treatment stages;
in response to a determination that the statistics-based model criteria is not satisfied, predict a response to the current stage of the wellbore treatment operation based on a physics-based model;
in response to a determination that the statistics-based model criteria is satisfied, predict the response to the current stage of the wellbore treatment operation based on a statistics-based model;
select, based on the predicted response, a next value of the at least one operational attribute for a next stage of the multiple treatment stages of the wellbore treatment operation; and
initiate adjustment of the pump in the next stage of the wellbore treatment operation based on the next value of the at least one operational attribute.

16. The system of claim 15, wherein the statistics-based model comprises a near neighbor learning model.

17. The system of claim 15, wherein the statistical range comprises previous values of the at least one operational attribute of previous treatment stages of the multiple treatment stages of a different well.

18. The system of claim 15, wherein the statistics-based model criteria comprises a number of the previous treatment stages exceeding a minimum threshold.

19. The system of claim 15, wherein the physics-based model comprises at least one of a fluid flow model, a proppant transport model, a diverter transport model, and a junction model.

20. The system of claim 15, wherein the at least one operational attribute comprises a pressure in the current well, a tip pressure, a diverter mass, and a flowrate of a fluid transmitted down the current well as part of the wellbore treatment operation.
